(19) United States
(12) Patent Application Publication
(10) Pub. No.: US 2024/0074047 A1
(43) Pub. Date: Feb. 29, 2024

(54) CONDUCTIVE BUMP STRUCTURE OF CIRCUIT BOARD AND MANUFACTURING METHOD THEREOF

(71) Applicant: ADVANCED FLEXIBLE CIRCUITS CO., LTD., ZHONGLI CITY (TW)

(72) Inventors: KUO-FU SU, ZHONGLI CITY (TW); CHIH-HENG CHUO, BADE CITY (TW); CLINTON LIN, NEW TAIPEI CITY (TW)

(21) Appl. No.: 18/321,999

(22) Filed: May 23, 2023

(30) Foreign Application Priority Data
Aug. 24, 2022 (TW) 111131953

(51) Int. Cl. H05K 1/11; H05K 3/00; H05K 3/40

(52) U.S. Cl. CPC H05K 1/11; H05K 1/119; H05K 3/0014; H05K 3/4007; H05K 2201/09045; H05K 2203/0723

(57) ABSTRACT

A conductive bump structure of a circuit board includes at least one composite conductive bump formed in at least one bump preservation region on a conductive layer of the circuit board. The composite conductive bump includes a raised portion and a conductive pillar. The raised portion is raised from a top surface of the conductive layer by a height. A bottom of the conductive pillar is in contact with and is combined with a curved top surface of the raised portion, and a top of the conductive pillar is raised upwards to protrude beyond the top planar surface of the conductive layer by a protrusion height.

### BACKGROUND OF THE INVENTION

### 1. Field of the Invention

The present invention relates to a structure of circuit board, and more particularly to a structure of a composite conductive bump formed on a conductive layer of a circuit board, and a manufacturing method thereof.

### 2. The Related Arts

Circuit boards have been widely used in various electronic devices, communication devices, and equipment and instruments. Specifically, flexible circuit boards are now a must of circuit component for such various electrical devices.

In the technology of flexible circuit boards, to lay out a circuit, it is generally necessary to form conductive path and conductive via structures in a flexible circuit board. To transmit a signal from a flexible circuit board to an electronic device, a piece of test equipment, or another circuit board, it is necessary to arrange contact points or conductive bumps at selected locations on the circuit board, and signal lines on the circuit board are connected through conductive vias, so that a path for transmission of electrical signals can be set up, through contact engagement or soldering, between two different components.

To make a conductive via structure in a circuit board, generally, a through hole is formed in the flexible circuit board, and then electroplating is applied to form a plating layer on a hole wall of the through hole. Etching is then applied to form a desired conductive path. However, to arrange a conductive bump structure on a circuit board, for the state of the art, is generally suffering certain problems to be further improved. For example, in the known technology of conductive bump structures of circuit boards, primarily, traditional electroplating processes are used for form the conductive bump structures, and as such, it is limited by the electroplating process. Further, the height of a conductive bump structure so finished is also limited.

### SUMMARY OF THE INVENTION

Thus, an objective of the present invention is to provide a conductive bump structure of a circuit board, wherein the conductive bump structure includes a structural configuration of a composite conductive bump.

Another objective of the present invention is to provide a manufacturing method of a conductive bump structure of a circuit board, in which a conductive bump structure of a high quality is formed on the circuit board through simple manufacturing steps.

To achieve the above objectives, the present invention provides a conductive bump structure of a circuit board, which comprises at least one composite conductive bump formed on a conductive layer of the circuit board in at least one bump preservation region. The composite conductive bump comprises a raised portion and a conductive pillar, wherein the raised portion is raised from a top planar surface of the conductive layer by a height, and a bottom of the conductive pillar is in contact with and is combined with a surface of the raised portion and a top of the conductive pillar is raised upwards to protrude beyond the top planar surface of the conductive layer by a protrusion height.

In the structure, a portion of the conductive layer that is located in the at least one bump preservation region is deformed as being raised by a stress acting thereon to elevate in the at least one bump preservation region by an elevation height to form the raised portion.

In the structure, an anti-oxidization conductive layer is further formed on the surface of the raised portion to enhance contact conductibility between the conductive pillar and the surface of the raised portion, wherein the anti-oxidization conductive layer comprises one of a metallic material, or an alloy material or a chemical oxidization resistant film containing the metallic material, and the metallic material is selected as one of silver, copper, nickel, gold, tin, and palladium.

In another embodiment, an electroplating region is formed on the conductive layer in the at least one bump preservation region to form the raised portion on the top planar surface of the conductive layer in the at least one bump preservation region.

In the structure, the conductive layer is bonded to the top surface of the insulation material layer by means of an adhesive layer or through an adhesive-free manufacturing process.

In the structure, the conductive pillar is further formed, on a top surface thereof, with a surface treatment layer, wherein the surface treatment layer is an anti-oxidization layer that provides a function of oxidization prevention or a soldering layer that provides a function of reducing contact resistance.

In respect of the efficacy, the present invention offers various advantages in respect of a simplified manufacturing process, a reduced electrical resistance of the conductive bump, easy adjustment of a height of the conductive bump as desired, and better reliability of contact conductibility.

A technical solution adopted in the present invention will be further described with reference to embodiments provided below and the attached drawings.

### BRIEF DESCRIPTION OF THE DRAWINGS

FIG. 1 is a perspective view showing arrangement of conductive bumps formed on a circuit board;

FIG. 2 is a cross-sectional view taken along section A-A of FIG. 1;

FIGS. 3A-3E show a sequence of manufacturing steps for manufacturing a conductive bump structure of a circuit board according to a first embodiment of the present invention;

FIGS. 4A-4F show a sequence of manufacturing steps for manufacturing a conductive bump structure of a circuit board according to a second embodiment of the present invention;

FIGS. 5A-5E show a sequence of manufacturing steps for manufacturing a conductive bump structure of a circuit board according to a third embodiment of the present invention; and

FIGS. 6A-6E show a sequence of manufacturing steps for manufacturing a conductive bump structure of a circuit board according to a fourth embodiment of the present invention.

### DETAILED DESCRIPTION OF THE PREFERRED EMBODIMENTS

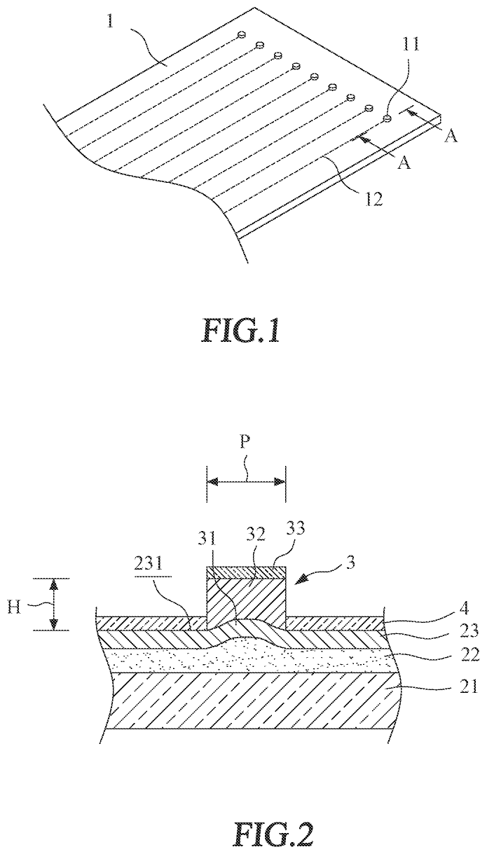

Referring to FIG. 1, which shows at least one conductive bump 11 arranged on a circuit board 1, the conductive bump 11 is connected to a conductive path 12. According to the requirements for different applications, it is possible to provide a plurality of conductive bumps 11 that are mutually spaced from each other on the circuit board 1 at a location adjacent to a front end edge thereof, or it is possible to provide one or more than one conductive bump 11 on the circuit board 1 at a selected location, in order to serve as circuit contacts. In applications, the circuit board 1 can be one of a rigid circuit board, a flexible circuit board, and a regid-flex circuit board.

FIG. 2 shows a cross-sectional view taken along section A-A of FIG. 1, and shows an insulation material layer 21 is combined, on a top thereof, with a conductive layer 23 by means of an adhesive layer 22. The insulation material layer 21 is selected as one of a liquid crystal polymer (LCP), polyimide (PI), modified polyimide (MPI), polyethylene terephthalate (PET), epoxy, modified epoxy, and Teflon. The adhesive layer 22 is selected as one of an insulating adhesive and an anisotropic conductive adhesive. Optionally, the adhesive layer 22 can alternatively be a hot melt adhesive. The conductive layer 23 can be a metallic material or a composite material containing the metallic material, and such a metallic material is selected as one of copper, silver, nickel, gold, and aluminum.

The conductive layer 23 is formed with a composite conductive bump 3 on a predetermined bump preservation region P. The composite conductive bump 3 is formed of a raised or bulged or swollen portion 31 and a conductive pillar 32.

The raised portion 31 of the composite conductive bump 3 is located in the bump preservation region P of the conductive layer 23 and has a curved top raised upward from a top planar surface 231 of the conductive layer 23 by a height. The conductive pillar 32 is arranged on the raised portion 31, and the conductive pillar 32 has a bottom that is set in contact with and is combined with the curved top surface of the raised portion 31, and a top raised upward to protrude beyond the top planar surface 231 of the conductive layer 23 by a protrusion height H.

The conductive pillar 32 can be of a conductive material containing one of silver, tin, aluminum, a conductive carbon paste, and a conductive particle adhesive layer, or a conductive material containing a mixture of such material components. The conductive pillar 32 may be further formed, on a top surface thereof, with a surface treatment layer 33. The surface treatment layer 33 can be an anti-oxidization layer that provides a function of oxidization prevention or a soldering layer that provides a function of reducing contact resistance in subsequent soldering.

An area of the conductive layer 23 that is located outside the bump preservation region P is covered with an insulation covering layer 4, which provides an effect of insulation and protection.

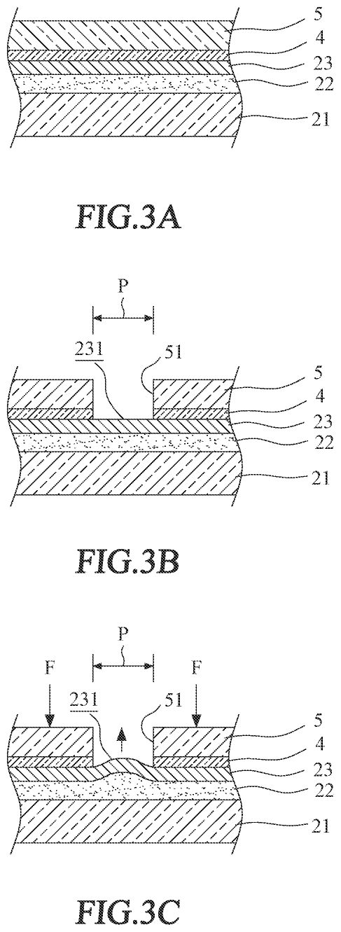

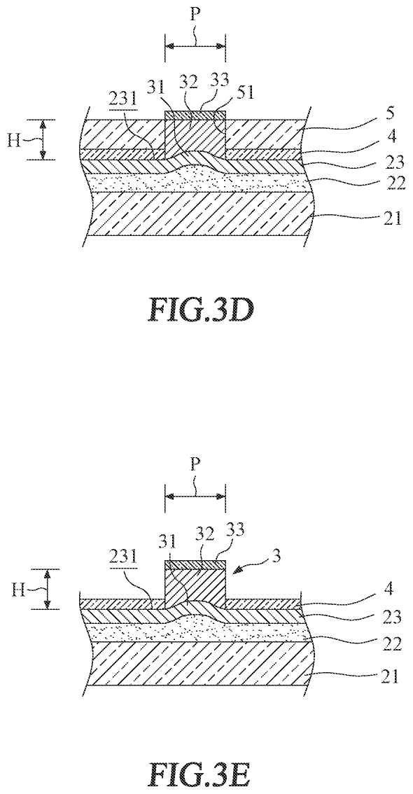

FIGS. 3A-3E show a sequence of manufacturing steps for manufacturing a conductive bump structure of a circuit board according to a first embodiment of the present invention. Firstly, as shown in FIG. 3A, a conductive layer 23 is bonded to and combined with a top surface of an insulation material layer 21 by means of an adhesive layer 22, and then, an insulation covering layer 4 and a release layer 5 are formed on the conductive layer 23.

According to requirements for different circuit layouts, at least one bump preservation region P is defined on the conductive layer 231 at one or more locations, which are preserved for forming a composite conductive bump 3 according to the present invention, and an opening 51 is formed in and penetrates through the release layer 5 and the insulation covering layer 4 at a location corresponding to the bump preservation region P, so as to expose a portion of a top planar surface 231 of the conductive layer 23 that is located in the bump preservation region P (as shown in FIG. 3B).

Then, a pressing force F is applied, in a direction from an upper side to a lower side, to the release layer 5, such that the bump preservation region P of the conductive layer 23 is acted upon by a compressing stress induced in the adhesive layer 22 to get deformed (as shown in FIG. 3C), thereby bulged or raised from the top planar surface 231 of the conductive layer 23 by a height so as to form the raised portion 31.

Afterwards, a conductive pillar 32 is formed in the opening 51 of the release layer 5 (as shown in FIG. 3D) by means of filling a conductive material into or implementing electroplating in the opening 51, such that a bottom of the conductive pillar 32 is in contact with and is combined with a surface of the raised portion 31, while a top of the conductive pillar 32 is raised upward to protrude beyond the top planar surface 231 of the conductive layer 23 by a raised or protrusion height H. Preferably, the conductive pillar 32 may be further formed, on a top surface thereof, with a surface treatment layer 33. The surface treatment layer 33 can be an anti-oxidization layer or a soldering layer.

In addition to printing and electroplating, forming of the conductive pillar 32 can be such that, after forming of the opening 51 in the release layer 5 and the insulation covering layer 4, a solder ball is implanted, through surface mounting technology, into the opening 51, and then reflowing and heating are applied in a reflow oven to form the conductive pillar 32 in the opening 51.

Finally, the release layer 5 is removed (as shown in FIG. 3E) to form the composite conductive bump 3 according to the present invention.

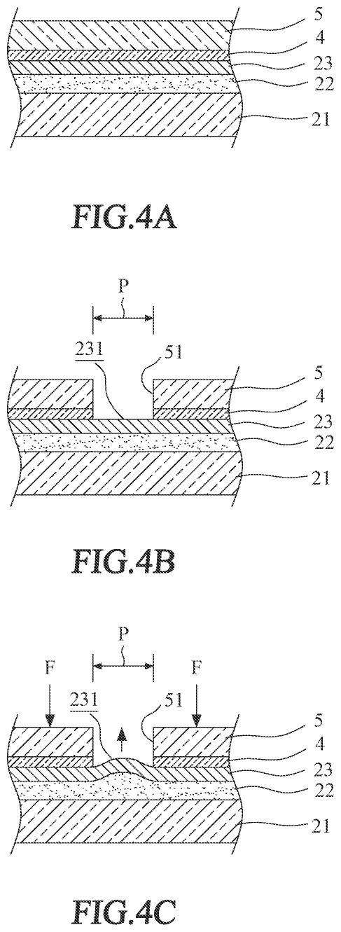

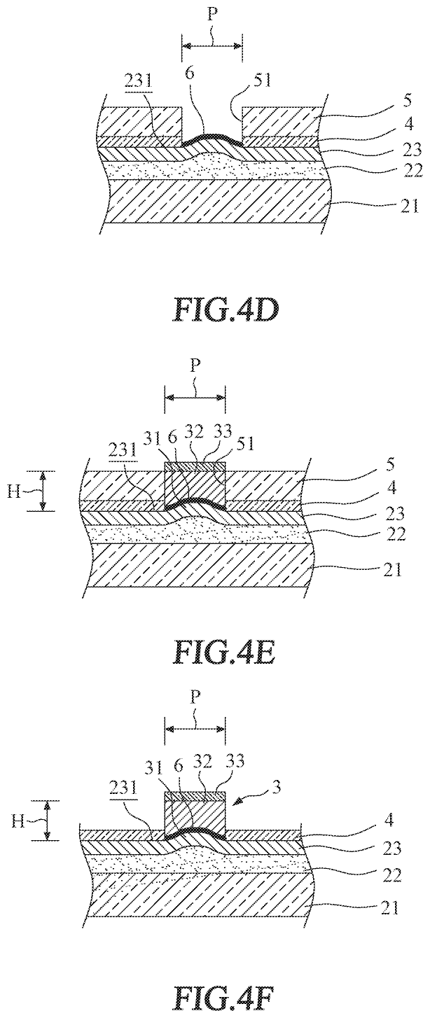

FIGS. 4A-4F show a sequence of manufacturing steps for manufacturing a conductive bump structure of a circuit board according to a second embodiment of the present invention. In the instant embodiment, some manufacturing steps (FIGS. 4A-4C and FIGS. 4E-4F) are identical to those of the manufacturing steps of the first embodiment (FIGS. 3A-3E), and a difference resides in that after the raised portion 31 is formed on the conductive layer 23 (as shown in FIG. 4C), an anti-oxidization conductive layer 6 is further formed on a curved top surface of the raised portion 31 (as shown in FIG. 4D) to enhance contact conductibility between the conductive pillar 32 and the curved top surface of the raised portion 31. the anti-oxidization conductive layer 6 can be one of a metallic material, an alloy material or a chemical oxidization resistant film containing such a metallic material, and such a metallic material can be selected as one of silver, copper, nickel, gold, or a composite material containing silver, copper, nickel, gold, tin, palladium. Preferably, the conductive pillar 32 may be further formed, on a top surface thereof, with a surface treatment layer 33. The surface treatment layer 33 can be an anti-oxidization layer or a soldering layer.

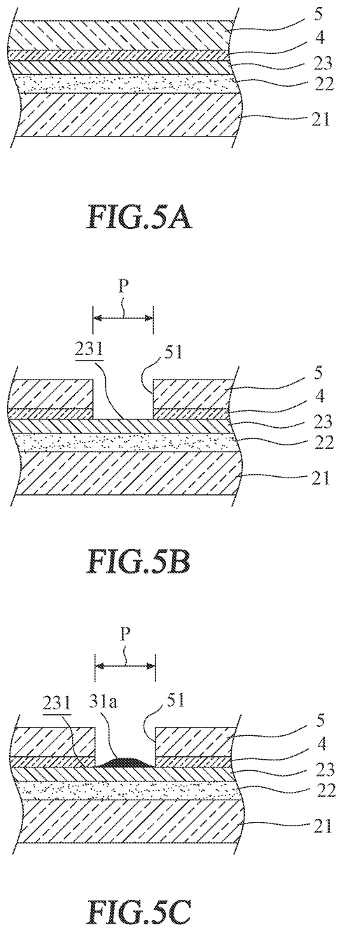

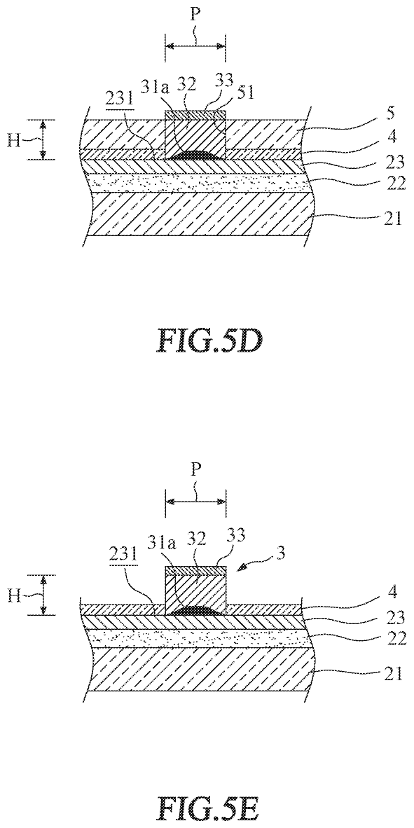

FIGS. 5A-5E show a sequence of manufacturing steps for manufacturing a conductive bump structure of a circuit board according to a third embodiment of the present invention. In the instant embodiment, some manufacturing steps (FIGS. 5A-5B) are identical to those of the manufacturing steps (FIGS. 3A-3B) of the first embodiment discussed above, yet after the opening 51 is formed in the release layer 5 and the insulation covering layer 4 at a location corresponding to the bump preservation region P (as shown in FIG. 5B), an electroplating region is formed, by means of for example electroplating technology, on a portion of the top planar surface 231 of the conductive layer 23 that is located in the bump preservation region P, so that a raised portion 31a (as shown in FIG. 5C) is formed on the portion of the top planar surface 231 of the conductive layer 23 that is located in the bump preservation region P.

Afterwards, a conductive pillar 32 is formed in the opening 51 of the release layer 5 (as shown in FIG. 5D), such that a bottom of the conductive pillar 32 is in contact with and is combined with a curved top surface of the raised portion 31a, and a top of the conductive pillar 32 is raised upwards to protrude beyond the top planar surface 231 of the conductive layer 23 by a raised or protrusion height H. Finally, the release layer 5 is removed (as shown in FIG. 5E) to form a composite conductive bump 3 according to the present invention. The raised portion 31a can be selected as one of silver, copper, nickel, gold, or a composite material containing silver, copper, nickel, or gold. Preferably, the conductive pillar 32 is further formed, on a top surface thereof, with a surface treatment layer 33. The surface treatment layer 33 can be an anti-oxidization layer or a soldering layer.

The embodiments discussed above are illustrated by taking an adhesive-involved circuit board substrate, and also a manufacturing process thereof, as an example for explanation, meaning the insulation material layer is bonded to and combined with the conductive layer by means of an adhesive layer. The present invention is also applicable to an adhesive-free circuit board substrate and a manufacturing process thereof.

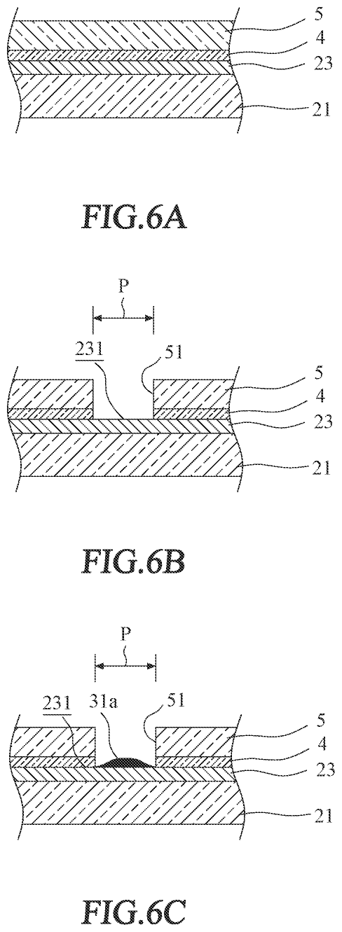

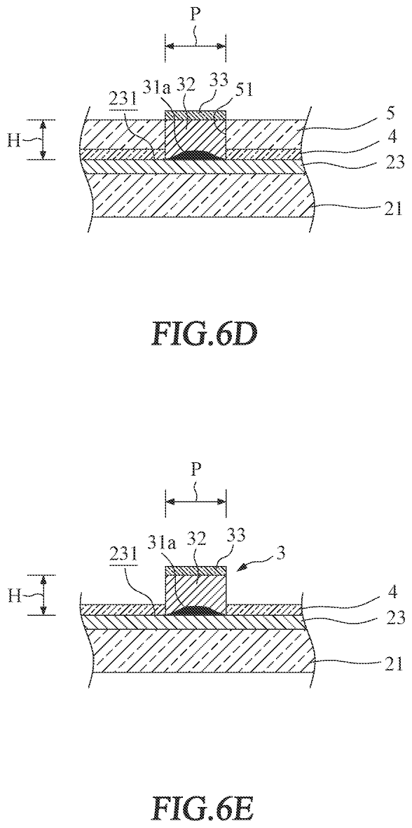

FIGS. 6A-6E show a sequence of manufacturing steps for manufacturing a conductive bump of a circuit board according to a fourth embodiment of the present invention that adopts an adhesive-free manufacturing process. In the instant embodiment, manufacturing steps are generally identical to those of the manufacturing steps shown in FIGS. 5A-5E, and a difference resides in that a conductive layer 23 is bonded to and combined with an insulation material layer 21 by means of adhesive-free technology (as shown in FIG. 6A), and then, an insulation covering layer 4 and a release layer 5 are formed on the conductive layer 23.

Then, an opening 51 is formed in the release layer 5 and the insulation covering layer 4 at a location corresponding to a bump preservation region P, so that a portion of a top planar surface 231 of the conductive layer 23 that is located in the bump preservation region P is exposed (as shown in FIG. 6B).

Then, an electroplating region is formed, by means of for example electroplating technology, on the portion of the top planar surface 231 of the conductive layer 23 that is located in the bump preservation region P, so that a raised portion 31a (as shown in FIG. 6C) is formed on the portion of the top planar surface 231 of the conductive layer 23 that is located in the bump preservation region P.

Afterwards, a conductive pillar 32 is formed in the opening 51 of the release layer 5 (as shown in FIG. 6D) by means of filling a conductive material into or implementing electroplating in the opening 51, such that a bottom of the conductive pillar 32 is in contact with and is combined with a curved top surface of the raised portion 31a, while a top of the conductive pillar 32 is raised upward to protrude beyond the top planar surface 231 of the conductive layer 23 by a raised or protrusion height H. Preferably, the conductive pillar 32 may be further formed, on a top surface thereof, with a surface treatment layer 33. The surface treatment layer 33 can be an anti-oxidization layer or a soldering layer.

Finally, the release layer 5 is removed (as shown in FIG. 6E) to form a composite conductive bump 3 according to the present invention.

The embodiments described above are provided only for illustrating structural arrangements of the present invention and are not intended to limit the scope of the present invention. Those skilled in the art may readily contemplate various modifications and variations of the embodiments described above within the structural arrangements and the spirits of the present invention, and such changes are considered failing in the scope of patent protection of the present invention that is defined in the following claims. Thus, the scope of protection of the present invention is only determined according to the appended claims.

What is claimed is:

1. A conductive bump structure of a circuit board, comprising:
an insulation material layer; and
a conductive layer formed on the insulation material layer, at least one bump preservation region being defined on the conductive layer;
wherein:
at least one composite conductive bump is formed in the at least one bump preservation region of the conductive layer, and the at least one composite conductive bump comprises:
a raised portion having a curved top surface raised upwards from a top planar surface of the conductive layer by a height in the at least one bump preservation region of the conductive layer; and
a conductive pillar having a bottom in contact with the curved top surface of the raised portion and a top raised upward to protrude beyond the top planar surface of the conductive layer by a protrusion height.

2. The conductive bump structure according to claim 1, wherein the circuit board comprises one of a rigid circuit board, a flexible circuit board, and a regid-flex circuit board.

3. The conductive bump structure according to claim 1, wherein an anti-oxidization conductive layer is further formed on the curved top surface of the raised portion to enhance contact conductibility between the conductive pillar and the surface of the raised portion, wherein the anti-oxidization conductive layer comprises one of a metallic material, or an alloy material or a chemical oxidization resistant film containing the metallic material, and the metallic material is selected as one of silver, copper, nickel, gold, tin, and palladium.

4. The conductive bump structure according to claim 1, wherein a portion of the conductive layer that is located in the at least one bump preservation region is deformed as being raised by a stress acting thereon to elevate in the at least one bump preservation region by an elevation height to form the raised portion.

5. The conductive bump structure according to claim 1, wherein an electroplating region is formed on the conductive layer in the at least one bump preservation region to form the raised portion on the top planar surface of the conductive layer in the at least one bump preservation region.

6. The conductive bump structure according to claim 1, wherein the conductive layer is bonded to and combined with the top surface of the insulation material layer by means of an adhesive layer, and the adhesive layer is selected as one of an insulating adhesive and an anisotropic conductive adhesive.

7. The conductive bump structure according to claim 1, wherein the conductive layer is bonded to the top surface of the insulation material layer through an adhesive-free manufacturing process.

8. The conductive bump structure according to claim 1, wherein the conductive pillar is further formed, on a top surface thereof, with a surface treatment layer, and the surface treatment layer is one of an anti-oxidization layer and a soldering layer.

9. The conductive bump structure according to claim 1, wherein:
the insulation material layer is selected as one of a liquid crystal polymer (LCP), polyimide (PI), modified polyimide (MPI), polyethylene terephthalate (PET), epoxy, modified epoxy, and Teflon;
the conductive layer comprises a metallic material or a composite material containing the metallic material, and the metallic material is selected as one of copper, silver, nickel, gold, and aluminum; and
the conductive pillar comprises a conductive material comprising one of silver, tin, aluminum, copper, a conductive carbon paste, and a conductive particle adhesive layer.

10. The conductive bump structure according to claim 1, wherein the conductive pillar is formed by subjecting a solder ball disposed on the raised portion to reflowing and heating to form the conductive pillar.

11. A method for forming a conductive bump structure on a circuit board, comprising the following steps:
(a) bonding a conductive layer on a top surface of an insulation material layer;
(b) defining at least one bump preservation region on the conductive layer;
(c) bonding a release layer on the conductive layer;
(d) forming at least one opening in the release layer at a location corresponding to the at least one bump preservation region, so as to expose a portion of a top planar surface of the conductive layer that is located in the at least one bump preservation region;
(e) forming at least one raised portion having a curved top surface on the conductive layer at a location corresponding to the at least one bump preservation region;
(f) forming at least one conductive pillar in the at least one opening of the release layer, such that a bottom of the at least one conductive pillar is in contact with the curved top surface of the at least one raised portion, and a top of the at least one conductive pillar is raised upwards to protrude beyond the top planar surface of the conductive layer by a protrusion height; and
(g) removing the release layer.

12. The method according to claim 11, further comprising, after Step (e), a step of forming an anti-oxidization conductive layer on the curved top surface of the raised portion.

13. The method according to claim 11, further comprising, before bonding the release layer on the conductive layer in Step (c), a step of forming an insulation covering layer on the conductive layer.

14. The method according to claim 11, wherein in Step (e), the raised portion is raised by a height by applying a pressing force, in a direction from an upper side to a lower side, to the release layer so as to cause the at least one bump preservation region of the conductive layer to deform as being acted upon by a compression stress induced in an adhesive layer to thereby form the raised portion.

15. The method according to claim 11, wherein in Step (e), the raised portion is formed by forming an electroplating region on a portion of the top planar surface of the conductive layer that is located in the at least one bump preservation region so as to form the raised portion on the top planar surface of the conductive layer in the at least one bump preservation region.

16. The method according to claim 11, wherein in Step (a), the conductive layer is bonded by an adhesive layer to the top surface of the insulation material layer.

17. The method according to claim 11, wherein in Step (a), the conductive layer is bonded, through an adhesive-free manufacturing process, to the top surface of the insulation material layer.

18. The method according to claim 11, wherein in Step (f), the at least one conductive pillar is further formed, on a top surface thereof, with a surface treatment layer, wherein the surface treatment layer comprises one of an anti-oxidization layer and a soldering layer.

19. The method according to claim 11, wherein in Step (f), the at least one conductive pillar is formed by subjecting a solder ball that is implanted through surface mounting technology in the at least one opening to reflowing and heating to form the at least one conductive pillar in the at least one opening.
